(19) United States
(12) Patent Application Publication
(10) Pub. No.: US 2019/0355524 A1
(43) Pub. Date: Nov. 21, 2019

(54) CAPACITOR

(71) Applicant: Murata Manufacturing Co., Ltd., Nagaokakyo-shi (JP)

(72) Inventor: Yoshiki Ueda, Nagaokakyo-shi (JP)

(21) Appl. No.: 16/527,212

(22) Filed: Jul. 31, 2019

Related U.S. Application Data
(63) Continuation of application No. PCT/JP2018/004519, filed on Feb. 9, 2018.

(30) Foreign Application Priority Data
Feb. 14, 2017 (JP) 2017-025273

(51) Int. Cl. H01G 4/33; H01G 4/12; H01G 4/005; H01G 4/10; H01G 9/00; H01L 49/02; H01G 9/052; H01G 9/07

(52) U.S. Cl. CPC H01G 4/33; H01G 4/12; H01G 4/005; H01G 9/07; H01G 9/0032; H01L 28/75; H01G 9/052; H01G 4/10

(57) ABSTRACT

A capacitor that includes a porous portion, a dielectric layer on the porous portion, an upper electrode on the dielectric layer, and a support supporting a bottom surface and at least a part of a side surface of the porous portion, and in which a difference in linear expansion coefficient between the porous portion and the support is within 8 ppm/K.

### CROSS REFERENCE TO RELATED APPLICATIONS

The present application is a continuation of International application No. PCT/JP2018/004519, filed Feb. 9, 2018, which claims priority to Japanese Patent Application No. 2017-025273, filed Feb. 14, 2017, the entire contents of each of which are incorporated herein by reference.

### FIELD OF THE INVENTION

The present invention relates to a capacitor.

### BACKGROUND OF THE INVENTION

In recent years, with high-density mounting of electronic devices, capacitors having higher electrostatic capacitance have been required. As such a capacitor, Patent Document 1 discloses a capacitor including a conductive metal base material including a porous portion, a dielectric layer on the porous portion, and an upper electrode on the dielectric layer, and including an electrostatic capacitance forming portion on only one principal surface side. In addition, Patent Document 2 discloses a capacitor that forms a capacitor structure including a porous metal sintered body, a dielectric layer, and an upper electrode on a substrate.
Patent Document 1: WO 2016/181865
Patent Document 2: U.S. Pat. No. 8,084,841

### SUMMARY OF THE INVENTION

In the capacitor of Patent Document 1, the bonding interface between a porous portion (high porosity portion) and a support for supporting the porous portion is the bottom surface of the porous portion alone, so that the porous structure is likely to be collapsed at a portion spaced apart from the bonding interface. When the porous structure is collapsed, the electrode causes a short, and the capacitor thereby fails to serve as a capacitor.

In the capacitor of Patent Document 2, a capacitor structure including a porous metal sintered body, a dielectric layer, and an upper electrode is formed in a recessed portion that has been previously formed on a substrate made of glass, ceramics, or silicon. The substrate has a relatively small linear expansion coefficient, and the porous metal sintered body has a relatively large linear expansion coefficient. Therefore, there is a large difference between these linear expansion coefficients. Further, unlike a metal substrate, the above-mentioned substrate does not have ductility and malleability. Thus, in a step of firing metal powders to produce a porous metal sintered body, a large stress generated on the metal powder/substrate interface when the temperature lowers from a high temperature during sintering cannot be relaxed, which may cause a mechanical breakage such as peeling-off, cracking, or the like on the interface. Even in the case of not causing peeling-off, cracking, or the like, warpage of the substrate can occur due to the difference in linear expansion coefficient.

Accordingly, an object of the present invention is to provide a capacitor having high electrostatic capacitance, and suppressing occurrence of a crack and less likely to cause warpage.

As the result of intensive studies to solve the above-mentioned problem, the present inventors have found that even in the case of using a porous portion which can achieve high electrostatic capacitance, occurrence of a crack, warpage, or the like can be suppressed by disposing the support for supporting the porous portion not only on the bottom surface of the porous portion but on the side surface thereof, and further, by reducing the difference in linear expansion coefficient between the material constituting the support and the material constituting the porous portion, and the present invention has been perfected thereby.

Therefore, the present invention is to provide a capacitor including a porous portion, a dielectric layer on the porous portion, an upper electrode on the dielectric layer, and a support supporting a bottom surface and at least a part of a side surface of the porous portion, and in which a difference in linear expansion coefficient between the porous portion and the support is within 8 ppm/K.

According to the present invention, by reducing the difference in linear expansion coefficient between the porous portion and the support, occurrences of cracks, warpage, or the like can be suppressed.

### BRIEF EXPLANATION OF THE DRAWINGS

FIG. 1 is a schematic cross-sectional view of a capacitor 1 according to an embodiment of the present invention.

FIG. 2 is a schematic plan view of a support 3 of the capacitor 1 shown in FIG. 1.

FIG. 3 is a schematic cross-sectional view of an electrostatic capacitance forming portion 2 of the capacitor 1 shown in FIG. 1.

FIG. 4 is a schematic cross-sectional view for describing a manufacturing method for the capacitor 1 shown in FIGS. 1 to 3.

FIG. 5 is a schematic cross-sectional view for describing the manufacturing method for the capacitor 1 shown in FIGS. 1 to 3.

FIG. 6 is a schematic cross-sectional view for describing the manufacturing method for the capacitor 1 shown in FIGS. 1 to 3.

FIG. 7 is a schematic cross-sectional view for describing the manufacturing method for the capacitor 1 shown in FIGS. 1 to 3.

FIG. 8 is a schematic cross-sectional view for describing the manufacturing method for the capacitor 1 shown in FIGS. 1 to 3.

FIG. 9 is a schematic cross-sectional view for describing the manufacturing method for the capacitor 1 shown in FIGS. 1 to 3.

FIG. 10 is a schematic plan view of a support according to another aspect of the present invention.

FIG. 11 is a schematic plan view of a support according to still another aspect of the present invention.

FIG. 12 is a schematic plan view of a support according to yet another aspect of the present invention.

FIG. 13 is a schematic cross-sectional view for describing a manufacturing method for the capacitor according to Example 3.

FIG. 14 is a schematic cross-sectional view for describing the manufacturing method for the capacitor according to Example 3.

FIG. 15 is a schematic cross-sectional view for describing the manufacturing method for the capacitor according to Example 3.

FIG. 16 is a schematic cross-sectional view for describing the manufacturing method for the capacitor according to Example 3.

FIG. 17 is a schematic cross-sectional view for describing the manufacturing method for the capacitor according to Example 3.

FIG. 18 is a schematic cross-sectional view of a capacitor according to Comparative Example.

### DETAILED DESCRIPTION OF THE INVENTION

The capacitor of the present invention will be described below in detail with reference to the drawings. The shapes and arrangements of the capacitors and the component elements according to the following embodiments are not limited to those illustrated examples.

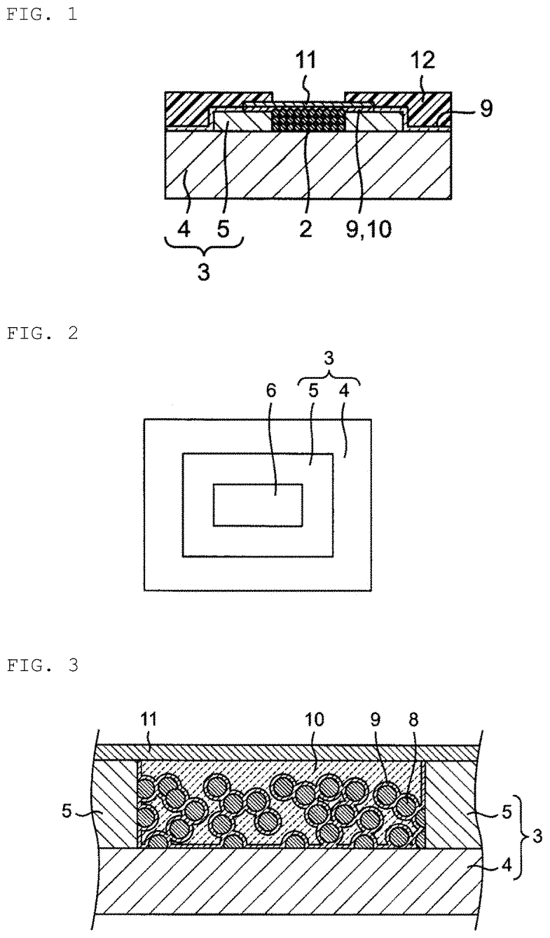

FIG. 1 shows a cross-sectional view of a capacitor 1 of the present embodiment, FIG. 2 shows a plan view of a support 3, and FIG. 3 shows an enlarged cross-sectional view of an electrostatic capacitance forming portion 2, all figures are in schematic form. As shown in FIGS. 1 to 3, the capacitor 1 of the present embodiment includes the electrostatic capacitance forming portion 2 and the support 3 for supporting the electrostatic capacitance forming portion 2. The support 3 includes a metal substrate 4 and a side wall 5. The side wall 5 is provided so as to surround the electrostatic capacitance forming portion 2. That is, the electrostatic capacitance forming portion 2 is formed in a cavity 6, and includes a porous portion 8 and the support 3 both serving as a lower electrode, a dielectric layer 9 located on the lower electrode, and an upper electrode 10 located on the dielectric layer 9. An external electrode 11 is provided on the upper electrode 10. The upper surface of the capacitor 1 except a part of the external electrode 11 is covered with a resin layer 12. In the capacitor 1, when a voltage is applied between the external electrode 11 and the metal substrate 4, the voltage is applied between the lower electrode, that is, the porous portion 8 and the support 3, and the upper electrode 10, which allows electric charge to be accumulated on the dielectric layer 9.

(Manufacturing Method)

The capacitor 1 as described above is manufactured in the following manner, for example.

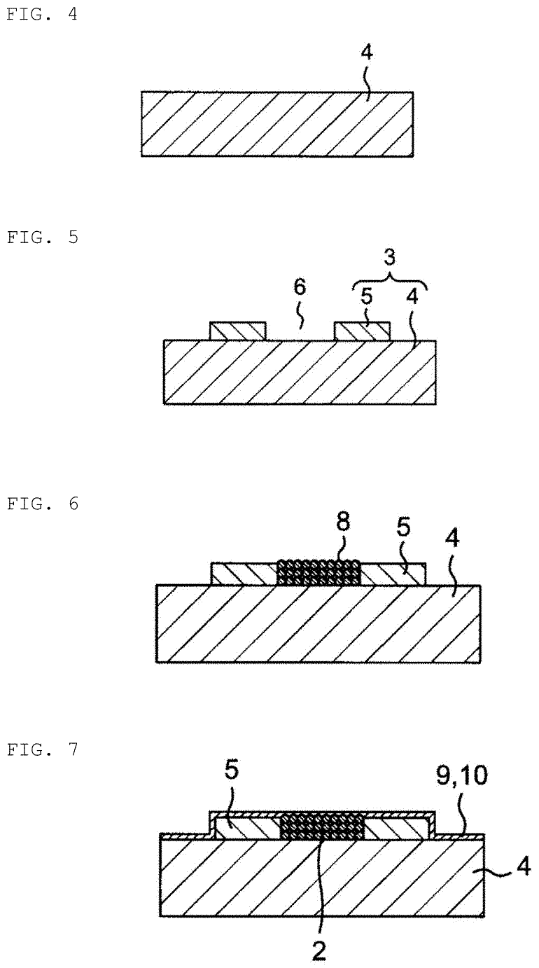

First, a metal substrate 4 is prepared (FIG. 4). In the present embodiment, the metal substrate 4 serves as the support of the porous portion and as the lower electrode.

The metallic material constituting the metal substrate 4 is not particularly limited as long as it is conductive, and examples thereof include Al, Ta, Ni, Cu, Ti, Nb, Fe, W, Mo, Au, Ir, Ag, Rh, Ru, and Co, or alloys thereof such as stainless steel and Duralumin. Preferably, the metallic material is Al, Ta, Ni, Cu, Ti, Nb, or Fe.

The thickness of the metal substrate 4 is not particularly limited and is preferably 3 μm or more, more preferably 10 μm or more, and can be, for example, 100 μm or more or 500 μm or more in order to enhance the mechanical strength of the capacitor. From the viewpoint of reducing the height of the capacitor, the thickness thereof is preferably 1000 μm or less and can be, for example, 500 μm or less or 100 μm or less.

The metal substrate 4 is usually a plate-like substrate, but in the case of having a small thickness, the metal substrate 4 may be a film-like substrate formed on the other substrate, for example, a silicon substrate. When the metal substrate 4 is formed on the other substrate, the other substrate can be removed after the capacitor is completed.

Next, a side wall 5 is formed on the metal substrate 4, to thereby form a cavity 6 surrounded by the side wall 5 (FIG. 5). The side wall 5 and the metal substrate 4 constitute a support 3.

The width of the side wall 5 is not particularly limited, and can be, for example, 3 μm or more and 300 μm or less, preferably 10 μm or more and 150 μm or less, and more preferably 20 μm or more and 80 μm or less. The side wall having a width of 3 μm or more increases its own strength, leading to increased strength of the obtained capacitor. Further, the side wall having a width of 300 μm or less allows a smaller capacitor to be easily obtained.

The height of the side wall 5 is appropriately determined depending on the size of the electrostatic capacitance forming portion 2 to be manufactured. The height thereof is not particularly limited and can be, for example, 5 μm or more and 200 μm or less, preferably 10 μm or more and 100 μm or less, and more preferably 20 μm or more and 100 μm or less.

The angle between the bottom surface of the cavity 6 and the side wall 5 thereof is not particularly limited and is, for example, 45° or more and 135° or less, preferably 60° or more and 120° or less, more preferably 70° or more and 110° or less, and further preferably 80° or more and 100° or less.

The size of the cavity 6 is appropriately determined depending on the size of the electrostatic capacitance forming portion 2 to be manufactured. For example, in the case of having a generally rectangular parallelepiped, the cavity 6 can have a size of length and width of, for example, 10 μm or more and 1 mm or less, preferably 30 μm or more and 500 μm or less; and more preferably 50 μm or more and 200 μm or less.

The shape of the above-mentioned cavity is not particularly limited, and is appropriately determined depending on the shape of the electrostatic capacitance forming portion to be manufactured. The cavity may have, for example, either a rectangular shape or a trapezoidal shape in cross section. The planar shape of the cavity may be any of a rectangle, a polygon, a circle, an ellipse, and the like.

The metallic material constituting the side wall 5 is not particularly limited as long as it is conductive, and examples thereof include Al, Ta, Ni, Cu, Ti, Nb, Fe, W, Mo, Au, Ir, Ag, Rh, Ru, and Co, or alloys thereof such as stainless steel and Duralumin. Preferably, the metallic material is Al, Ta, Ni, Cu, Ti, Nb, or Fe.

In a preferred aspect, the metallic material constituting the metal substrate and the metallic material constituting the side wall are preferably a metallic material having a smaller difference in thermal expansion coefficient between these metallic materials, for example, the difference within 8 ppm/K, preferably within 5 ppm/K, and more preferably within 3 ppm/K. More preferably, the metallic material constituting the metal substrate and that constituting the side wall can be the same.

The method of forming the side wall 5 is not particularly limited and examples thereof include plating, screen printing, and the like. Preferably, the side wall is formed by pattern plating.

In the preferred aspect, the side wall is formed by pattern plating. Specifically, first, a resist is applied onto the metal substrate, the applied resist is exposed to light so as to expose a side wall-forming portion of the metal substrate, and then developed. Thereafter, the side wall is formed by electrolytic plating, and the resist is then removed, so that the side wall can be formed.

Next, a metal sintered body (porous portion 8) is formed in the cavity 6 (FIG. 6).

The above-mentioned metal sintered body can be obtained by firing one or more metal powders. The metal sintered body may be formed by firing the metal powder in the cavity 6 or a metal sintered body separately obtained by firing the metal powder may be placed in the cavity 6. Preferably, the metal sintered body is formed by firing the metal powder in the cavity 6. The formation of the metal sintered body in the cavity 6 allows the metal sintered body and the support to be bonded by metal bonding, so that the strength of the capacitor improves and the equivalent series resistance (ESR) of the capacitor can be reduced.

The metal powder to be added in the cavity may be either a liquid phase synthetic powder or a vapor phase synthetic powder. The metal powder can be added in the cavity as a dispersion liquid, and the dispersion liquid may include one or more dispersants, plasticizers, solvents, and binder components.

The capacitor using the porous portion formed of the metal sintered body as described above can obtain a higher electrostatic capacitance density because it has an extremely large surface area.

Here, the “metal powder” used herein means an aggregated body of metal particles, showing substantially one peak in the particle size distribution. That is, even a metal powder made of the same constituent element, for example, Ni is regarded as a different metal powder if having a different particle size distribution. In addition, the shape of the metal powder is not particularly limited, and may be a spherical shape, an oval shape, a needle shape, a rod shape, a wire shape, or the like. The metal powder may be subjected to processing for increasing the surface area.

The metallic material constituting the metal powder is not particularly limited as long as it is conductive, and examples thereof include Al, Ti, Ta, Nb, Ni, Cu, W, Mo, Au, Ir, Ag, Rh, Ru, Co, and Fe, or alloys thereof.

Preferably, the metallic material constituting the metal powder is Ni, Cu, W, Mo, Au, Ir, Ag, Rh, Ru, Co, or Fe. Using these materials can reduce the ESR of the metal sintered body. In addition, these materials have lower resistivities and high melting points, so that annealing is allowed at high temperature and a high-quality dielectric film can be obtained in the following steps.

The metallic material constituting the metal powder is preferably a metallic material having a smaller difference in thermal expansion coefficient with the metallic material constituting the metal substrate or the metallic material constituting the side wall, preferably the metallic material constituting the entire support (i.e., the metal substrate and the side wall), for example, the difference within 8 ppm/K, preferably within 5 ppm/K, and more preferably within 3 ppm/K. More preferably, the metallic material constituting the metal powder can use the same metal as the metallic material constituting the metal substrate or the metallic material constituting the side wall. Further preferably, the metallic material constituting the metal powder can use the same metal as the metallic material constituting the metal substrate and the metallic material constituting the side wall.

The average particle diameter of the metal powder is not particularly limited, and can be, for example, 10 nm or more and 600 nm or less, preferably 30 nm or more and 400 nm or less, and more preferably 50 nm or more and 200 nm or less. The average particle diameter within this range can increase an effective area for serving as a capacitor.

In the preferred aspect, the metal sintered body can be obtained by mixing at least two metal powders and then firing the metal powders thus mixed. As described above, mixing and firing of two or more metal powders can provide a porous portion with high strength, so that both high electrostatic capacitance density and high strength can be satisfied.

In one aspect, the mixture of the metal powders includes at least two metal powders having different average particle diameters, for example, two, three, or four metal powders. Using the metal powders having different average particle diameters can improve the strength of the sintered body even though the metal powders are fired at a lower temperature.

Here, the “average particle diameter” of the metal powder means an average particle diameter D50 (a particle diameter corresponding to 50% in the volume-based cumulative percentage). Such average particle diameter D50 can be measured with, for example, a dynamic light scattering type particle size analyzer (manufactured by Nikkiso Co., Ltd., UPA).

In addition, the average particle diameter of the metal powders in the metal sintered body can be determined by processing the metal sintered body by focused ion beam (FIB) processing into a thin section, photographing a predetermined region (e.g., 5 μm×5 μm) of this thin section sample using a transmission electron microscope (TEM), and subjecting the obtained image to image analysis.

In another aspect, the mixture of the metal powders includes at least two metal powders having different melting points, for example, two, three, or four metal powders. Using the metal powders having different melting points can improve the strength of the sintered body even though the metal powders are fired at a lower temperature.

The combination of the metal powder predominantly contained in the metal sintered body and the metal powder having a low melting point is not particularly limited, and examples thereof include a combination of Ni and Cu.

The above-mentioned metal sintered body has a high porosity. From the viewpoint of increasing the specific surface area to further increase the capacitance of the capacitor, the metal sintered body can preferably have a porosity of 30% or more, and more preferably 40% or more. It also preferably has a porosity of 90% or less, and more preferably 80% or less, from the viewpoint of enhancing the mechanical strength.

In this specification, the “porosity” refers to the proportion of voids in the porous portion. The porosity can be determined as follows. The void in the above-mentioned porous portion can be finally filled with a dielectric layer and an upper electrode in the process of preparing the capacitor. The above-mentioned “porosity” is, however, determined by regarding the filled portions as voids without considering the filled substance.

First, the porous portion is processed by focused ion beam (FIB) processing into a thin section. A predetermined region (e.g., 5 μm×5 μm) of this thin section sample is photographed using a transmission electron microscope (TEM). The obtained image is subjected to image analysis, thereby determining the area where a metal of the porous portion is present. Then, the porosity can be calculated by the following equation.

Porosity (%)=((Measured area−Area where metal of base material is present)/Measured area)×100

The thickness of the metal sintered body, that is, the porous portion, is not particularly limited and can be appropriately determined depending on the purpose. The thickness thereof can be, for example, 5 μm or more and 200 μm or less, preferably 10 μm or more and 100 μm or less, and more preferably 20 μm or more and 100 μm or less. It is to be noted that the thickness of the porous portion means a thickness of the porous portion in the case of assuming that all pores are filled up.

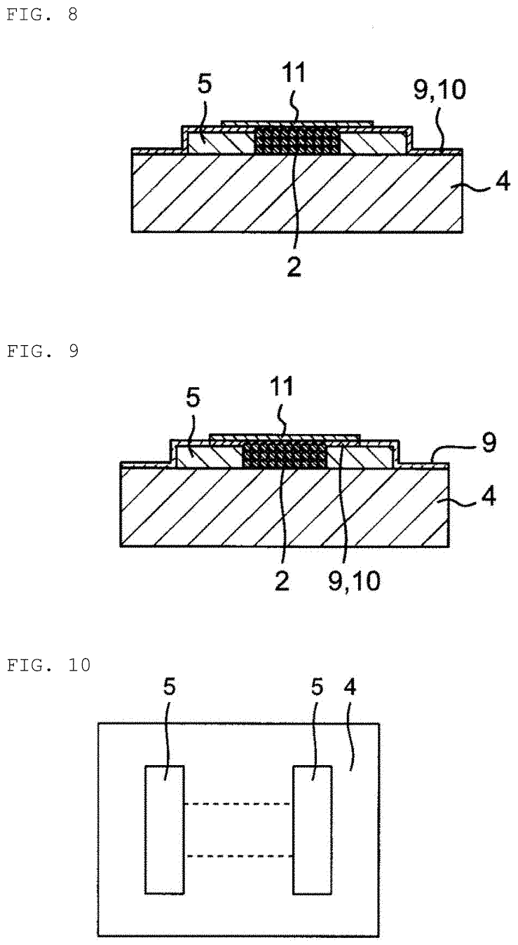

Next, a dielectric layer 9 and an upper electrode 10 are formed on the metal sintered body (porous portion 8) of the cavity 6 (FIG. 7).

The material that forms the dielectric layer 9 mentioned above is not particularly limited as long as the material has an insulating property, and examples thereof preferably include metal oxides such as AlOₓ (e.g., Al₂O₃), SiOₓ (e.g., SiO₂), AlTiOₓ, SiTiOₓ, HfOₓ, TaOₓ, ZrOₓ, LaOₓ, HfSiOₓ, ZrSiOₓ, TiZrOₓ, TiZrWOₓ, TiOₓ, SrTiOₓ, PbTiOₓ, BaTiOₓ, BaSrTiOₓ, BaCaTiOₓ, and SiAlOₓ; metal nitrides such as AlNₓ, SiNₓ, and AlSCNₓ; or metal oxynitrides such as AlOₓN_{y}, SiOₓN_{y}, HfSiOₓN_{y}, and SiCₓO_{y}Nz, and AlOₓ, HfOₓ, TaOₓ, and HfSiOₓ are preferable. It is to be note that the above-mentioned formulas are merely intended to represent the constitutions of the materials, but not intended to limit the compositions. More specifically, x, y, and z attached to O and N may have any value larger than 0, and the respective elements including the metal elements may have any presence proportion. In addition, the dielectric layer may be a layered compound including a plurality of different layers.

The thickness of the dielectric layer 9 is not particularly limited, and for example, preferably 3 nm or more and 100 nm or less, and more preferably 5 nm or more and 50 nm or less. When the dielectric layer has a thickness of 3 nm or more, the insulating property can be enhanced, which makes it possible to reduce leakage current. In addition, when the dielectric layer has a thickness of 100 nm or less, higher electrostatic capacitance can be obtained.

The dielectric layer 9 may have a single layer or multiple layers.

The dielectric layer 9 is preferably formed by a vapor phase method such as a vacuum deposition method, a chemical vapor deposition (CVD) method, a sputtering method, an atomic layer deposition (ALD) method, or a pulsed layer deposition (PLD) method, or a method using a supercritical fluid. An ALD method is more preferable because it can form a more homogeneous and dense film even in microscopic regions of pores of the high porosity portion.

The material constituting the above-mentioned upper electrode 10 is not particularly limited as long as the material is conductive, and examples thereof include Ni, Cu, Al, W, Ti, Ag, Au, Pt, Zn, Sn, Pb, Fe, Cr, Mo, Ru, Pd, and Ta, and alloys thereof, such as CuNi, AuNi, and AuSn, and metal nitrides and metal oxynitrides, such as TiN, TiAlN, TiON, TiAlON, and TaN, and conductive polymers (e.g., PEDOT (poly(3,4-ethylene dioxythiophene)), polypyrrole, polyaniline), and TiN and TiON are preferable.

The thickness of the upper electrode 10 is not particularly limited, and for example, preferably 3 nm or more, and more preferably 10 nm or more. When the upper electrode has a thickness of 3 nm or more, the resistance of the upper electrode itself can be reduced.

The upper electrode 10 may have a single layer or multiple layers.

The upper electrode 10 may be formed by an ALD method. The use of the ALD method can further increase the capacitance of the capacitor. The upper electrode may be formed by, as another method, a method such as CVD, plating, bias sputtering, Sol-Gel, or conductive polymer filling, which can coat the dielectric layer and substantially fill pores of the base material. Preferably, a conductive film is formed on the dielectric layer by the ALD method, and pores may be filled thereon by another approach with a conductive material, preferably a substance having a lower electrical resistance, thereby forming the upper electrode. This constitution can efficiently achieve a higher capacitance density and lower equivalent series resistance (ESR).

Next, the external electrode 11 is formed on the upper electrode 10 (FIG. 8).

The material constituting the above-mentioned external electrode 11 is not particularly limited and examples thereof include metals such as Sn, Ni, Cu, Ti, TiN, Al, Au, Pb, Pd, and Ag, and alloys thereof, and conductive polymers.

The method of forming the external electrode 11 is not particularly limited and for example, CVD, electrolytic plating, electroless plating, vapor deposition, sputtering, baking of a conductive paste, or the like can be used, and electrolytic plating, electroless plating, vapor deposition, or sputtering is preferable.

Next, a portion not covered with the external electrode 11 in the upper electrode 10 is removed (FIG. 9). After removing, the dielectric layer 9 is exposed. As described above, the removal of the upper electrode around the capacitor can prevent the upper electrode and the lower electrode from causing a short in the end surface of the capacitor. In particular, in the case of manufacturing the capacitor as an aggregate substrate, the short as described above can be suppressed when the aggregate substrate is cut into individual pieces.

The removal method is not particularly limited and dry etching, for example, Ar ion milling or reactive ion etching (RIE), can be used.

Next, the upper surface of the capacitor except a part of the external electrode 11 is covered with a resin layer 12.

The material constituting the above-mentioned resin layer 12 is not particularly limited as long as the material is an insulating material, and heat resistance resin is preferable. Specific examples thereof include polyimides, polybenzoxazoles, polyethylene terephthalate, benzocyclobutene resins, and epoxy resins. Further, the resin layer may include a filler for adjusting a linear expansion coefficient, such as a Si filler.

The method of forming the resin layer 12 is not particularly limited, and the resin layer 12 can be formed by, for example, applying a coating of resin, and then curing the coat. As the method of applying a coating of resin, spin coating, dispenser coating, spray coating, screen printing, or other method can be used. Alternatively, the resin layer may be formed by affixing a resin sheet separately formed.

As described above, the capacitor 1 of the present embodiment 1 is manufactured (FIG. 1).

In the above-mentioned embodiment, the capacitor 1 is manufactured as one capacitor, but may be preferably obtained as an aggregate substrate of a capacitor. The aggregate substrate can be split into capacitors using a dicing blade, various laser devices, a dicer, various cutters, or a mold.

Since the difference in thermal expansion coefficient between the porous portion 8 and the support 3 is small, the capacitor of the present invention is less likely to cause stress inside due to temperature change during manufacturing, in particular, during firing, in reflow processing during mounting to a substrate, or the like, so that a crack may be less likely to occur in the dielectric layer 9.

As described above, since the capacitor of the present invention can be manufactured as an aggregate substrate, the size of the entire capacitor and the electrostatic capacitance can be easily adjusted by adjusting the size of each block.

While the capacitor of the present invention has been described based on the capacitor 1, it is not intended to limit the capacitor of the present invention to the above-mentioned embodiments and manufacturing methods, but the capacitor of the present invention may be further design-changed within the gist of the invention.

For example, the capacitor of the present invention can essentially serve as a capacitor in the state of FIG. 7. Therefore, the external electrode 11, the resin layer 12, and the like are not essential constitution in the present invention and may not be present.

In the above-mentioned embodiment, the side wall 5 is formed on the metal substrate 4. However, as another method, a part of the metal substrate 4 is removed by laser, etching, or the like to be dug down, which may form the side wall 5 and the cavity 6. In this case, the side wall becomes a part of the metal substrate.

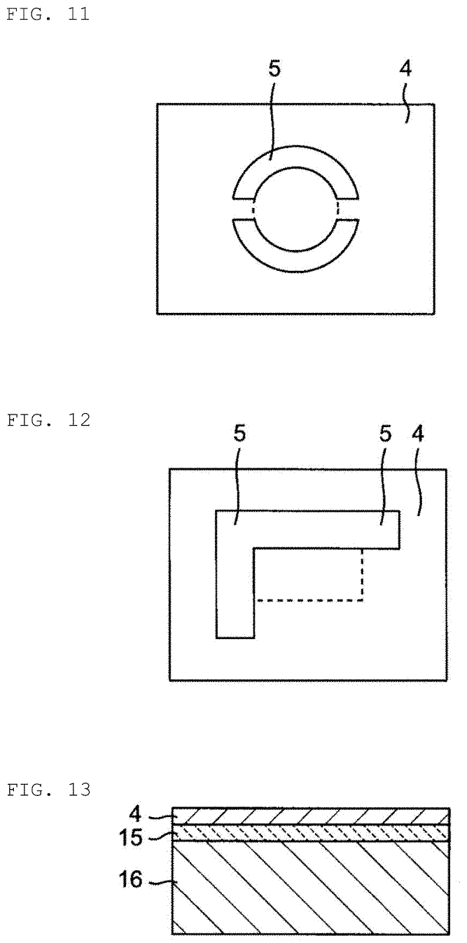

In the above-mentioned embodiment, the side wall 5 is formed around the entire electrostatic capacitance forming portion 2. However, the side wall 5 may be formed on only a part of the side surface of the electrostatic capacitance forming portion 2. For example, as shown in FIG. 10, the side wall 5 may be formed on only two opposed side surfaces of the electrostatic capacitance forming portion 2. In addition, as shown in FIG. 11, the electrostatic capacitance forming portion 2 is formed in a circular shape, and two arc-shaped side walls 5 may be partially formed around the electrostatic capacitance forming portion 2 having the circular shape so as to be opposed to each other. Further, as shown in FIG. 12, the side wall 5 may be formed on only two adjacent side surfaces of the electrostatic capacitance forming portion 2. It is to be noted that in FIGS. 10 to 12, the range surrounded by a broken line indicates a portion where the electrostatic capacitance forming portion 2 is present.

In the above-mentioned embodiment, the capacitor 1 includes one electrostatic capacitance forming portion 2, but the present invention is not limited thereto. For example, the capacitor 1 may include two or more electrostatic capacitance forming portions, for example, two, three, or four. By adjusting the number of electrostatic capacitance forming portions, the electrostatic capacitance can be easily adjusted. In addition, when a plurality of electrostatic capacitance forming portions are formed and each of them is surrounded by the side wall, the strength of the capacitor can be enhanced.

In the above-mentioned embodiment, the porous portion is a metal sintered body, but is not limited thereto. For example, the porous portion may be a porous base material including a porous portion other than a sintered body. In one aspect, a part of the metal substrate is etched so that the bottom and side surfaces of the base material remain, to thereby simultaneously form a cavity, a side wall, and a porous portion.

In the above-mentioned embodiment, the dielectric layer is provided directly on the porous portion. However, a binder layer, for example, the other conductive layer, may be provided between the porous portion and the dielectric layer.

In a preferred aspect, the other layer is not present on the lower surface side of the metal substrate (i.e., the surface opposed to the surface where the porous portion is present).

In another aspect, in the case where the other layer is present on the lower surface side of the metal substrate, the difference in thermal expansion coefficient between the other layer, and the metal substrate and the porous portion is within 8 ppm/K, preferably within 5 ppm/K, and more preferably within 3 ppm/K.

In another aspect, when the other layer is present on the lower surface side of the metal substrate, an intermediate layer for stress relaxation is present between the metal substrate and the other layer. As the intermediate layer, for example, a layer of silicon oxide (in particular, silicon dioxide) is present.

### EXAMPLES

### Example 1

As the metal substrate, a nickel substrate (thickness of 100 μm) was prepared (FIG. 4). A resist was applied onto the metal substrate, the applied resist was exposed to light so as to expose a side wall-corresponding portion of the metal substrate, and then developed. Thereafter, the side wall of nickel was formed by electrolytic plating, to thereby form a plurality of cavities on the metal substrate (FIG. 5). The side wall had a height of 50 μm and a width of 50 μm. The angle between the side wall and the metal substrate was approximately 70°. Each of the cavities had a length of 100 μm and a width of 100 μm.

Ni metal powders having an average particle diameter of 200 nm were dispersed in ethanol with a ball mill using a 1 mmφ zirconia ball. Polyvinyl alcohol was added to this dispersion to prepare a metal powder slurry. This slurry was added to each of the cavities using a dispenser and then dried. The dried metal powder layer had a thickness of approximately 30 μm. The metal substrate having the metal powder layers formed in the cavities was degreased in a firing furnace at 200 to 300° C., and then subjected to heat treatment at 300 to 650° C. for five minutes under a N₂ atmosphere, so that a metal sintered body was obtained (FIG. 6).

Next, an AlOₓ film (25 nm) was formed by the ALD method and was then set as a dielectric layer. A Ru film (20 nm) was formed on the dielectric layer by the ALD method, and was then set as an upper electrode (FIG. 7).

Subsequently, vapor deposition was performed to form a pattern in a region covering the cavities and its surrounding region on the upper electrode, and the pattern was then plated to form a Ni plating electrode, and this electrode was set as an external electrode (FIG. 8).

Next, a portion not in contact with the external electrode was removed from the upper electrode by reactive ion etching using a mixing gas of CF₄ and O₂ (FIG. 9). The upper surface of the capacitor except a part of the external electrode was then covered with polyimide to form a resin layer (FIG. 1). Thus, an aggregate substrate including a plurality of capacitors was obtained.

Next, the aggregate substrate thus obtained was split into capacitors using a laser, to thereby produce a capacitor of Example 1.

### Example 2

A nickel film (thickness of 3 μm) was formed on the silicon substrate by a sputtering method, instead of using the nickel substrate of Example 1 as the metal substrate. Then, a metal sintered body, a dielectric layer, an upper electrode, an external electrode, and a resin layer were formed in the same manner as in Example 1. Subsequently, the upper surface of the substrate was affixed to a foaming release sheet, the rear surface of the silicon substrate was removed by grinding to obtain an aggregate substrate. The aggregate substrate thus obtained was split into capacitors using a laser, the foaming release sheet was disconnected to produce a capacitor of Example 2.

### Example 3

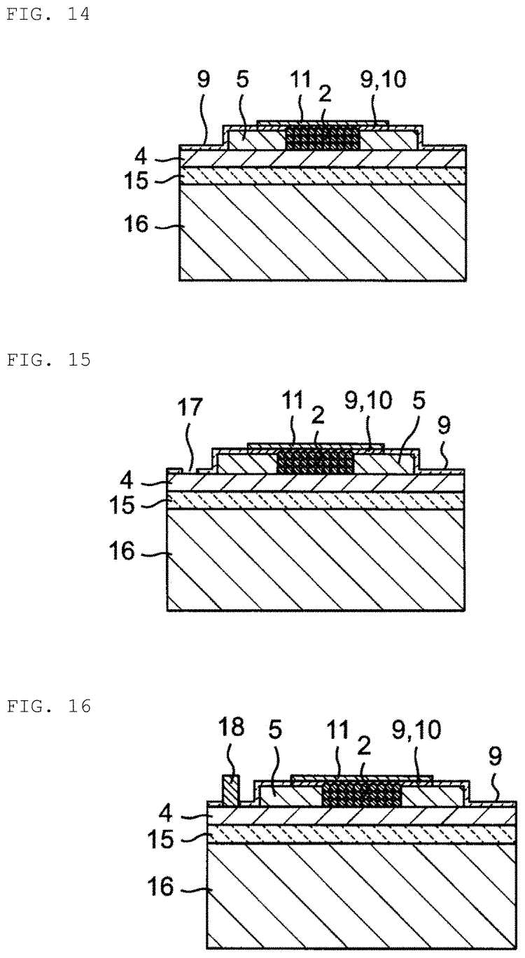

A nickel film (thickness of 3 μm) was formed on a silicon substrate 16 including a SiO₂ film 15 (thickness of 500 nm) by a sputtering method, instead of using the nickel substrate of Example 1 as the metal substrate (FIG. 13).

Then, a metal sintered body, a dielectric layer, an upper electrode, and an external electrode were formed in the same manner as in Example 1, and a part of the upper electrode was removed (FIG. 14).

Further, a resist was applied onto the substrate, the resist was exposed to light so as to expose a part of the dielectric layer (AlOₓ film) exposed by removing a part of the upper electrode, and then developed. Next, dry etching was carried out by ion milling to remove a part of the AlOₓ film, so that the above-mentioned nickel film was exposed (exposed portion 17) (FIG. 15).

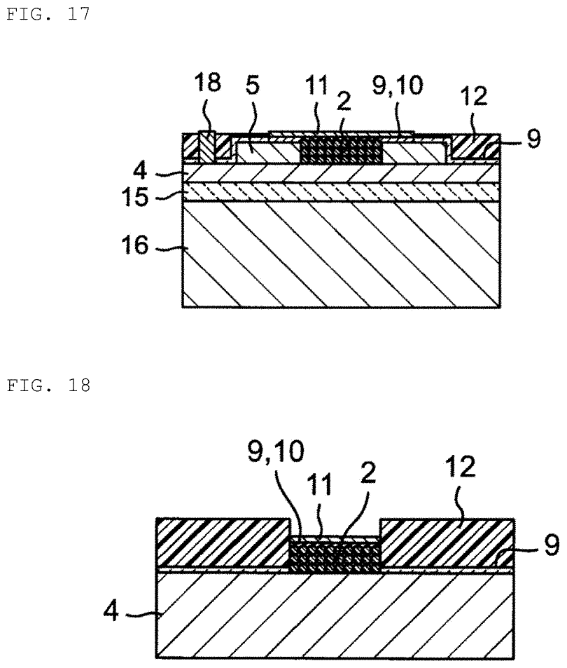

Next, an extended electrode 18 was formed on the exposed portion 17 by Ni plating (FIG. 16). The upper surface of the capacitor except the extended electrode and a part of the external electrode was then covered with polyimide to form a resin layer (FIG. 17). The aggregate substrate thus obtained was split into capacitors using a laser, to thereby produce a capacitor of Example 3.

### Example 4

As shown in FIG. 10, a capacitor of Example 4 was produced in the same manner as in Example 1, except that the side wall was formed on only two opposed side surfaces of the electrostatic capacitance forming portion.

### Example 5

As shown in FIG. 11, a capacitor of Example 5 was produced in the same manner as in Example 1, except that the electrostatic capacitance forming portion was formed in a circular shape (radius of 50 μm), and two side walls were partially formed in arc shape around the electrostatic capacitance forming portion so as to be opposed to each other.

### Example 6

As shown in FIG. 12, a capacitor of Example 6 was produced in the same manner as in Example 1, except that the side wall was formed on only two adjacent side surfaces of the electrostatic capacitance forming portion.

### Comparative Example 1

A capacitor of Comparative Example 1 was produced in the same manner as in Example 1, except that the side wall was not formed (FIG. 18).

### Comparative Example 2

A silicon substrate was used instead of the metal substrate, and a cavity was formed on the silicon substrate by partially removing the silicon substrate by anisotropic etching. That is, the bottom surface and the side wall of the cavity were made of silicon. Subsequently, a Ni film (3 μm) was formed on the surface of the silicon substrate by a sputtering method and was then set as a lower electrode.

Then, a metal sintered body, a dielectric layer, an upper electrode, an external electrode, and a resin layer were formed in the same manner as in Example 1, so that an aggregate substrate was obtained. The aggregate substrate thus obtained was split into capacitors using a laser, to thereby produce a capacitor of Comparative Example 2.

### Test Example

Regarding capacitors obtained in Examples 1 to 6 and Comparative Examples 1 to 2 described above, a leakage current was measured at the time of applying 5 V. The results are shown in Table 1.

TABLE 1

| | Leakage current |
|---|---|
| Example 1 | Less than 1 × 10⁻⁷ A/cm² |
| Example 2 | Less than 1 × 10⁻⁷ A/cm² |
| Example 3 | Less than 1 × 10⁻⁷ A/cm² |
| Example 4 | Less than 1 × 10⁻⁷ A/cm² |
| Example 5 | Less than 1 × 10⁻⁷ A/cm² |
| Example 6 | Less than 1 × 10⁻⁷ A/cm² |
| Comparative Example 1 | Short |
| Comparative Example 2 | Short |

From the above results, it was confirmed that the capacitor of the present invention caused an extremely small leakage current. On the other hand, it was confirmed that the capacitors of Comparative Examples caused a short, failing to serve as a capacitor. In the capacitor of Comparative Example 1, it is believed that the support had a bottom surface alone, failing to sufficiently support the porous portion, so that a crack occurs in the dielectric layer, causing a short in the upper electrode and the lower electrode. In the capacitor of Comparative Example 2, it is believed that the thermal expansion coefficient of Si is 2.4 ppm/K and that of Ni is 12.8 ppm/K, so that the difference between these thermal expansion coefficients causes a crack in the dielectric layer during manufacturing, causing a short in the upper electrode and the lower electrode.

The capacitor according to the present invention has high electrostatic capacitance and is less likely to cause a crack, so that it is suitably used in various electronic devices.

### DESCRIPTION OF REFERENCE SYMBOLS

1a: Capacitor
2: Electrostatic capacitance forming portion
3: Support
4: Metal substrate
5: Side wall
6: Cavity
8: Porous portion
9: Dielectric layer
10: Upper electrode
11: External electrode
12: Resin layer
15: SiO₂ film
16: Silicon substrate
17: Exposed portion
18: Extended electrode

1. A capacitor comprising:
a porous portion;
a dielectric layer on the porous portion;
an upper electrode on the dielectric layer; and
a support supporting a bottom surface and at least a part of a side surface of the porous portion,
wherein a difference between a first linear expansion coefficient of the porous portion and a second linear expansion coefficient of the support is within 8 ppm/K.

2. The capacitor according to claim 1, wherein the difference between the first linear expansion coefficient of the porous portion and the second linear expansion coefficient of the support is within 5 ppm/K.

3. The capacitor according to claim 1, wherein the difference between the first linear expansion coefficient of the porous portion and the second linear expansion coefficient of the support is within 3 ppm/K.

4. The capacitor according to claim 1, wherein the porous portion includes a metal sintered body.

5. The capacitor according to claim 1, wherein a material of the support is selected from Al, Ta, Ni, Cu, Ti, Nb, Fe, W, Mo, Au, Ir, Ag, Rh, Ru, and Co, or alloys thereof.

6. The capacitor according to claim 1, wherein the support includes a substrate portion that supports the bottom surface of the porous portion, and a side wall portion that supports the part of the side surface of the porous portion.

7. The capacitor according to claim 6, wherein a difference between a third linear expansion coefficient of the substrate portion and a fourth linear expansion coefficient of the side wall portion is within 8 ppm/K.

8. The capacitor according to claim 7, wherein the difference between the third linear expansion coefficient of the substrate portion and the fourth linear expansion coefficient of the side wall portion is within 5 ppm/K.

9. The capacitor according to claim 7, wherein the difference between the third linear expansion coefficient of the substrate portion and the fourth linear expansion coefficient of the side wall portion is within 3 ppm/K.

10. The capacitor according to claim 7, wherein a difference between a third linear expansion coefficient of the substrate portion and a fourth linear expansion coefficient if the side wall portion is within 8 ppm/K.

11. The capacitor according to claim 6, wherein the side wall portion surrounds the entirety of the porous portion.

12. The capacitor according to claim 6, wherein the side wall portion surrounds only two opposed side surfaces of the porous portion.

13. The capacitor according to claim 6, wherein the side wall portion includes two arc-shaped side walls.

14. The capacitor according to claim 6, wherein the side wall portion is only on two adjacent side surfaces of the porous portion.

15. The capacitor according to claim 1, wherein a material of the porous portion and a material of the support are the same.

16. The capacitor according to claim 1, wherein the support entirely supports the bottom surface and the side surface of the porous portion.

17. The capacitor according to claim 1, wherein the upper electrode does not extend to an outer edge of the dielectric layer.

18. The capacitor according to claim 1, wherein the support defines a cavity within which the porous portion is located, the cavity having a rectangular, polygonal, circular, or elliptical planar shape.

19. The capacitor according to claim 1, wherein the porous portion has a porosity of 30% to 90%.

20. The capacitor according to claim 1, further comprising a resin layer covering at least part of an upper surface of the capacitor.
